(19) United States
(12) Patent Application Publication
(10) Pub. No.: US 2025/0336626 A1
(43) Pub. Date: Oct. 30, 2025

(54) INTERRUPTER SNAP BRACKET

(71) Applicant: Hubbell Incorporated, Shelton, CT (US)

(72) Inventor: Patrick Dale Maddox, Mt. Olive, AL (US)

(21) Appl. No.: 19/188,605

(22) Filed: Apr. 24, 2025

Related U.S. Application Data
(60) Provisional application No. 63/638,611, filed on Apr. 25, 2024.

(51) Int. Cl. H01H 33/42; H05K 7/14

(52) U.S. Cl. CPC H01H 33/42; H05K 7/14

(57) ABSTRACT

An interrupter device includes a drive shaft, a first extension, and a bracket. The drive shaft includes a first end, a second end, and a central portion between the first and second ends. The first end has a first splined shape and a first end opening. The second end has a second splined shape. The central portion is cylindrical. The first extension includes a first portion and a second portion. The first portion has a cavity with a shape complementary to the first splined shape and a first portion opening extending into the cavity. The second portion includes a plurality of teeth. The bracket includes a bracket opening with a plurality of bracket teeth spaced around an inner surface of the bracket opening. The first end can be received in the cavity so that the first end opening is aligned with the first portion opening to receive a pin.

### CROSS-REFERENCE TO RELATED APPLICATION

This application claims the benefit of U.S. Provisional Application No. 63/638,611, filed Apr. 25, 2024, the entire contents of which are incorporated herein by reference in its entirety.

### FIELD

The present disclosure relates to an arc interrupter. More particularly, the present disclosure relates to a splined connection between various elements of an arc interrupter.

### BACKGROUND

An arc interrupter is a device that is attached between electrical switches and minimizes or prevents electrical arcing. Interrupter devices generally rotate between the switches to prevent arcing.

The arc interrupter device generally includes a drive shaft and an extension that need to be assembled together. There are different assembly configurations, so a technician generally needs to assemble the drive shaft and extension before installing. Existing drive shafts are threaded on both ends to accommodate different set ups.

Depending on the desired set up, an extension is screwed onto an end of the drive shaft. To prevent the loosening of the threaded connection, the technician uses a pin connection to further connect the drive shaft and extension. To create the pinned connection, the technician needs to manually drill into the drive shaft and the extension to create the hole for the pin to be inserted through.

Not only is this process manually taxing, but it is also imprecise. The technician may be unable to determine if the location for the hole is in the proper position. If the technician drills in the wrong place, he must replace the part and drill again. This process is time consuming and also creates waste if parts need to be thrown away because they have improperly drilled holes.

### SUMMARY

Various examples of the present disclosure can overcome various of the aforementioned and other disadvantages associated with known arc interrupters and offer new advantages as well.

According to one aspect of various examples of the present disclosure there is provided a drive shaft for an arc interrupter. The drive shaft includes a first end having a pre-drilled hole formed in the manufacturing process.

According to another aspect of various examples of the present disclosure, there is provided a drive shaft for an arc interrupter. The drive shaft includes a shaft body and a first end. The shaft body having a cylindrical shape and the first end having a splined shape.

According to another aspect of various examples of the present disclosure, there is provided an arc interrupter device that includes a drive shaft and an extension. The drive shaft includes a first pre-drilled aperture at a first end. The extension includes a cavity and a second pre-drilled hole that extends into the cavity. The first end can be received within the cavity so that the first pre-drilled hole and the second pre-drilled hole are aligned. The aligned first and second pre-drilled holes can receive a pin to couple the drive shaft to the extension.

According to another aspect of various examples of the present disclosure, there is provided an arc interrupter device that includes a drive shaft and an extension. The drive shaft includes a shaft body having a cylindrical shape and a first end having a splined shape. The extension includes a cavity with a shape complementary to the splined shape. The first end can be received within the cavity.

According to another aspect of various examples of the present disclosure, there is provided an interrupter device that includes a drive shaft, a first extension, and a bracket. The drive shaft can be driven to rotate in a first direction and/or in a second direction. The drive shaft includes a first end, a second end, and a central portion. The first end has a first splined shape and a first end opening. The second end has a second splined shape. The central portion is disposed between the first end and the second end. The central portion has a cylindrical shape. The first extension is removably connected to the first end. The first extension includes a first portion and a second portion. The first portion has a cavity with a shape complementary to the first splined shape. The first portion also has a first portion opening extending into the cavity. The second portion is directly coupled to the first portion and includes a plurality of teeth. The bracket includes a bracket opening with a plurality of bracket teeth spaced around an inner surface of the bracket opening. The first end can be received in the cavity so that the first end opening is aligned with the first portion opening. The first end opening and the first portion can receive a pin. The drive shaft and the first extension can rotate together.

According to another aspect of various examples of the present disclosure, there is provided an interrupter device that includes a drive shaft, a first extension removably connected to a first end of the drive shaft, and a bracket. The drive shaft can be driven to rotate in a first direction and/or in a second direction. The drive shaft including a first end having a first splined shape and a first end opening. The first extension includes a first portion that has a cavity with a shape complementary to the first splined shape, and a second portion directly coupled to the first portion and includes a plurality of teeth. The bracket includes a bracket opening with a plurality of bracket teeth spaced around an inner surface of the bracket opening. The first end can be received in the cavity so that the first end opening is aligned with the first portion opening. The plurality of teeth on the second portion engages the plurality of bracket teeth. The drive shaft and the first extension are configured to rotate together.

According to another aspect of various examples of the present disclosure, there is provided an interrupter device that includes a drive shaft, a first extension removably connected to a first end of the drive shaft, and a bracket. The drive shaft can be driven to rotate in a first direction and/or in a second direction. The drive shaft includes a central portion that extends along a shaft axis, a first end that has a first end opening perpendicular to the shaft axis, and a second end opposite to the first end. The first extension includes a first portion that has a cavity that extends along a cavity axis and a first portion opening that extends into the cavity along an opening axis perpendicular to the cavity axis. The first extension also includes a second portion directly coupled to the first portion and including a plurality of teeth. The bracket includes a bracket opening with a plurality of bracket teeth spaced around an inner surface of the bracket opening. The first end can be inserted into the cavity along the cavity axis so that the first end opening is aligned with the first portion opening. The first end opening and the first portion can receive a pin. The plurality of teeth on the second portion engage the plurality of bracket teeth. The drive shaft and the first extension can rotate together.

According to another aspect of various examples of the present disclosure, there is provided a method of manufacturing and assembling an interrupter device. The method includes forming a drive shaft with a cylindrical body and a splined first end, wherein the splined first end is formed with a first aperture; forming an extender with a splined cavity and a second aperture; aligning the splined first end with the splined cavity and inserting the first end into the cavity; and inserting a first fastener through the first aperture and the second aperture to secure the drive shaft to the extender.

According to another aspect of various examples of the present disclosure, there is provided a method of assembling an interrupter device. The method includes inserting a first end of a drive shaft into a cavity of an extender, wherein the first end includes a pre-formed first aperture and the extender includes a pre-formed second aperture; aligning the first aperture with the second aperture; and inserting a first fastener through the first aperture and the second aperture to secure the drive shaft to the extender. The first end includes a first splined shape and the cavity includes a second splined shape that is complementary to the first splined shape.

The disclosure herein should become evident to a person of ordinary skill in the art given the following enabling description and drawings. The drawings are for illustration purposes only and are not drawn to scale unless otherwise indicated. The drawings are not intended to limit the scope of the disclosure. The following enabling disclosure is directed to one of ordinary skill in the art and presupposes that those aspects within the ability of the ordinarily skilled artisan are understood and appreciated.

### BRIEF DESCRIPTION OF THE DRAWINGS

Various aspects and advantageous features of the present disclosure will become more apparent to those of ordinary skill when described in the detailed description of preferred examples and reference to the accompany drawing wherein:

FIG. 1 is a perspective view of an assembled interrupter device.

FIG. 2 is an exploded view of the interrupter device of FIG. 1.

FIG. 3 is a perspective view of a shaft of the interrupter device of FIG. 1.

FIG. 4 is an end view of the shaft of FIG. 3.

FIG. 5 is a side view of the shaft of FIG. 3.

FIG. 6 is a perspective view of an extension end connectable to the shaft of FIG. 3.

FIG. 7 is a top view of the extension end of FIG. 6.

FIG. 8 is an end view of the extension end of FIG. 6.

FIG. 9 is a detail view of the extension end in FIG. 8, viewed along detail 9-9.

FIG. 10 is a perspective view of an arm bracket usable with the interrupter device of FIG. 1.

FIG. 11 is a top view of the arm bracket of FIG. 10.

FIG. 12 is a side view of the arm bracket of FIG. 10.

FIG. 13 is a front view of the arm bracket of FIG. 10.

FIG. 14 is a detail view of the arm bracket of FIG. 13, viewed along detail 14-14.

FIG. 15 is a perspective view of a return spring bracket usable with the interrupter device of FIG. 1.

FIG. 16 is a side view of the return spring bracket of FIG. 15.

FIG. 17 is a detail view of the return spring bracket of FIG. 16, viewed along detail 17-17.

FIG. 18 is a top view of the return spring bracket of FIG. 15.

### DETAILED DESCRIPTION

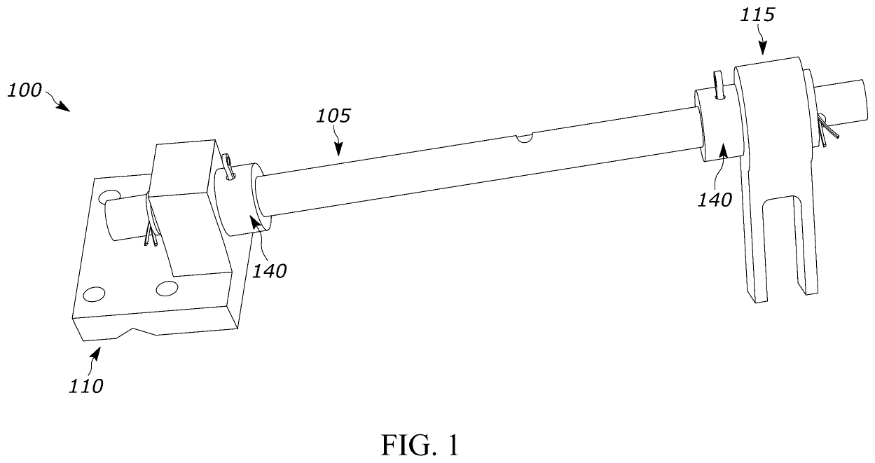

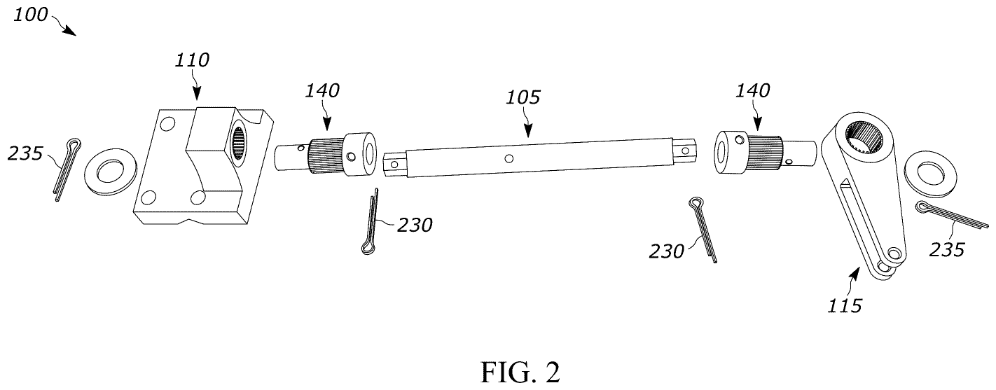

FIGS. 1 and 2 illustrate an interrupter device 100. The interrupter device 100 may be attached to any number of switches (not shown) to act as an arc interruption device, which may assist in limiting arcing from occurring while operating an electrical device. The interrupter device 100 includes a drive shaft 105 extending between an actuating arm bracket 110 and a return spring bracket 115.

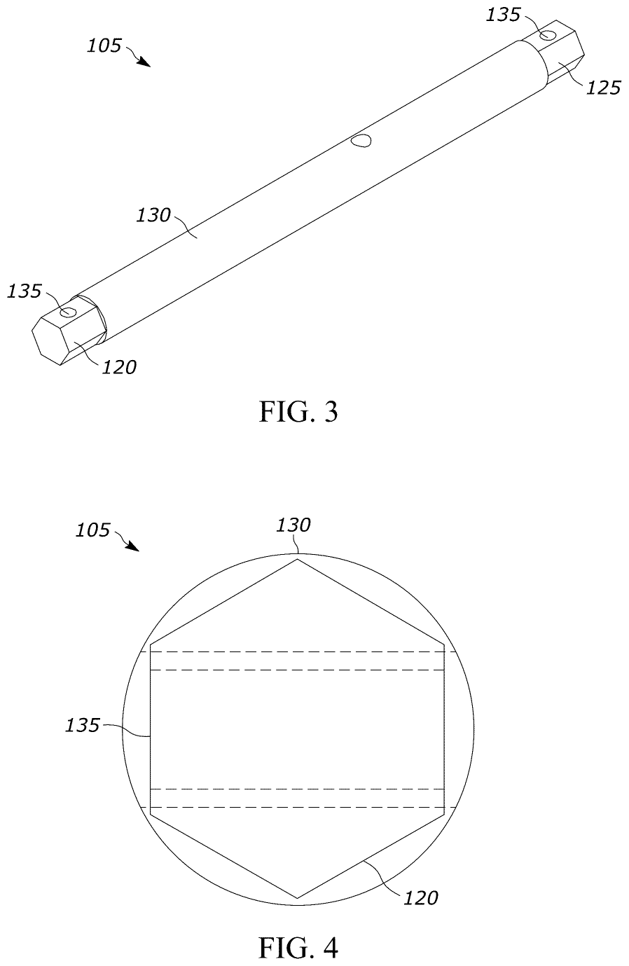

FIGS. 3 to 5 illustrate the drive shaft 105, which is formed as an elongated member. Specifically, the drive shaft 105 may extend between a first end 120 and a second end 125. A length between the first end 120 and the second end 125 may be greater than a width of the drive shaft 105.

As shown in FIGS. 3 and 4, the drive shaft 105 may be a substantially cylindrical member. For example, a central portion 130 that is disposed between the first and second ends 120, 125 may have a substantially cylindrical shape. However, in other examples, the central portion 130 may have a different shape (e.g., with an angled body).

In some forms, the first end 120 and/or the second end 125 may have a different shape than the central portion 130. For example, the first end 120 and/or the second end 125 may not be cylindrical in shape. In the illustrated example, the first and second ends 120, 125 may be splined and have a hexagonal cross-section, although any other shape may be used (e.g., triangle, rectangle, pentagon, etc.).

As shown in FIG. 4, the spline in the first and/or second ends 120, 125 may be formed so that at least a portion of the respective first and/or second ends 120, 125 has a width that is less than the width of the central portion 130. For example, a length between opposing sides of the first end 120 is less than an outer width of the central portion 130.

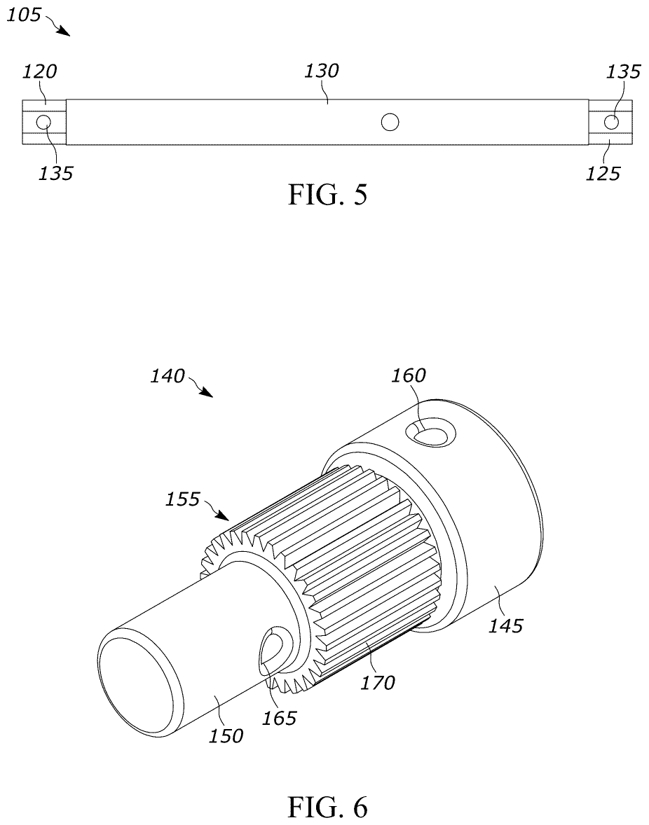

As shown in FIGS. 3 and 5, the first end 120 and the second end 125 each include an end aperture 135. Each end aperture 135 may extend entirely through the respective one of the first and second ends 120, 125 (although other examples may include an end aperture 135 that extends only partially through the respective end 120, 125). Each end aperture 135 may be pre-formed in the respective first and second ends 120, 125 (e.g., formed during the manufacturing process).

FIGS. 6 to 9 illustrate an extension 140 that may be connected to the drive shaft 105. The extension 140 may include a first portion 145, a second portion 150, and a third portion 155 that is disposed between the first and second portions 145, 150.

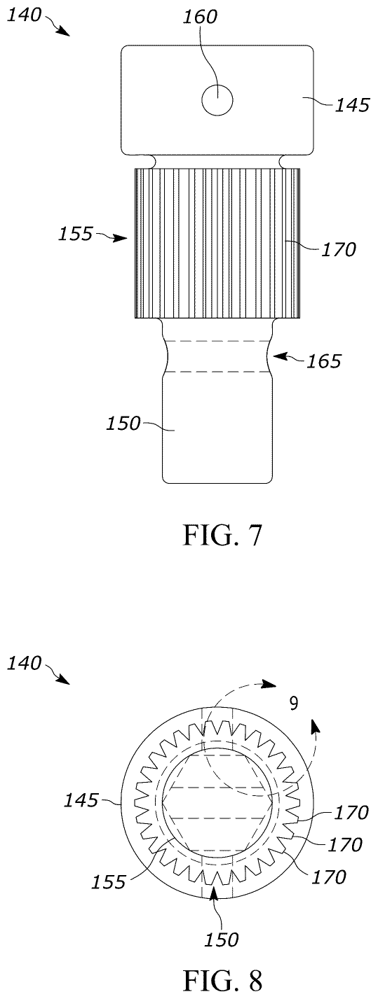

As shown in FIGS. 6 and 7, the first portion 145 may be a substantially cylindrical portion. The first portion 145 may also be at least partially hollow to receive one of the first end 120 or the second end 125 of the drive shaft 105. Although not illustrated, an interior of the first portion 145 may substantially correspond to the shape of the first and second ends 120, 125. For example, the interior of the first portion 145 may have a hexagonal shape.

In some forms, the outer diameter of the first portion 145 may be between about 0.1 inches and about 5 inches. In some forms, the outer diameter of the first portion 145 may be between 0.5 inches and about 2.5 inches. In some forms, the outer diameter of the first portion 145 may be between about 0.75 inches and about 1.25 inches. In some forms, the outer diameter of the first portion 145 may be about 1 inch.

In some forms, the first portion 145 may include an aperture 160. The aperture 160 may be pre-formed in the first portion 145 (e.g., formed during the manufacturing process). As described in more detail below, the aperture 160 may be aligned with the aperture 135 of the respective end 120, 125 when the end 120, 125 is received within the first portion 145.

With continued reference to FIGS. 6 and 7, the second portion 150 may be a substantially cylindrical portion. The diameter of the second portion 150 may be less than the diameter of the first portion 145. The second portion 150 may include a hole 165, which may be pre-formed in the second portion 150 (e.g., formed during the manufacturing process). The hole 165 may extend entirely through the second portion 150. In some forms, the hole 165 may be disposed proximate to the third portion 155.

In some forms, the outer diameter of the second portion 150 may be between about 0.1 inches and about 3 inches. In some forms, the outer diameter of the second portion 150 may be between about 0.25 inches and about 2 inches. In some forms, the outer diameter of the second portion 150 may be between about 0.35 inches and about 1 inch. In some forms, the outer diameter of the second portion 150 may be about 0.5 inches.

The third portion 155 may be a substantially cylindrical body disposed between the first and second portions 145, 150. The diameter of the third portion 155 may be less than the diameter of the first portion 145 but greater than the diameter of the second portion 150.

In some forms, the outer diameter of the third portion 155 may be between about 0.1 inches and about 4 inches. In some forms, the outer diameter of the third portion 155 may be between about 0.25 inches and about 3 inches. In some forms, the outer diameter of the third portion 155 may be between about 0.5 inches and about 1 inch. In some forms, the outer diameter of the third portion 155 may be about 0.75 inches.

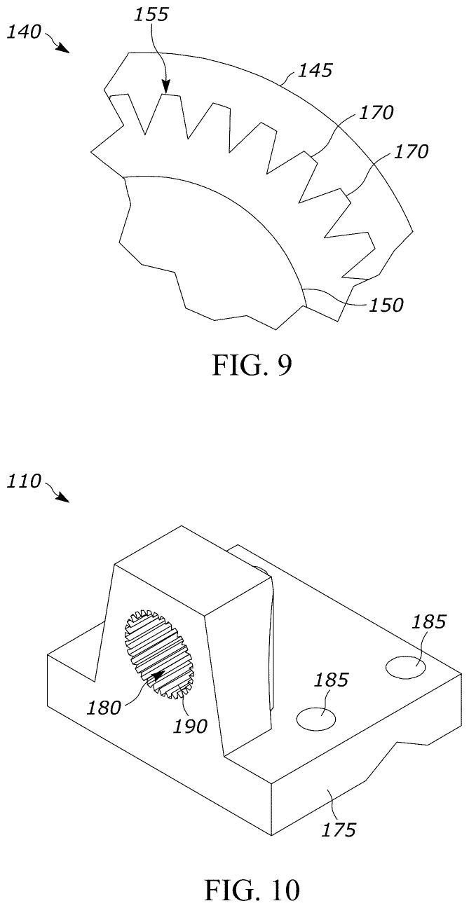

As shown in FIGS. 8 and 9, some forms of the third portion 155 may include a plurality of teeth 170. The illustrated teeth 170 may extend around the entire perimeter of the third portion 155, although in other examples, the teeth 170 may extend around only a portion of the perimeter of the third portion 155.

In certain forms, the third portion 155 may include thirty evenly spaced teeth 170 around the perimeter. For example, each tooth 170 may be about twelve degrees from each adjacent tooth 170.

In one form, the outermost edge of each tooth 170 (e.g., a radially outermost point) may be at least a partially linear surface. However, other examples may include at least one tooth 170 with a curved outer edge or an edge that extends to a point.

FIGS. 10 to 14 illustrate the arm actuating bracket 110. In the illustrated example, includes a base 175 and a passage 180 that extends from the base 175. The base 175 and the passage 180 may be formed as a single, integral piece. Although in other examples, the passage 180 may be formed as a separate piece

In some forms, the base 175 may be a substantially rectangular body, although any other shape may be used. The base 175 may include one or more mounting apertures 185. The mounting apertures 185 may be spaced apart along the base 175 and may each receive a fastener to secure the base 175 in place.

In some forms, the passage 180 may be disposed on one end of the base 175. For example, an opening in the passage 180 may be flush with an edge of the base 175. The passage 180 may extend only a partly along the length of the base 175. In other words, the passage 180 may not extend entirely to an opposite end of the base 175. In this way, the arm actuating bracket 110 may be asymmetrical about an axis substantially perpendicular to the passage 180. However, in other examples, the passage 180 may extend along the entire length of the base 175 and/or may be disposed in a position when the arm actuating bracket 110 is symmetrical about the axis perpendicular to the passage 180.

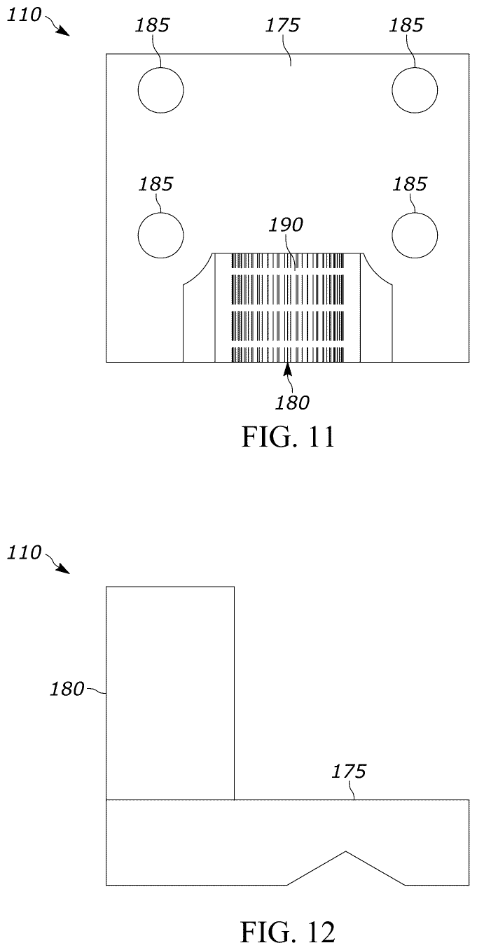

As shown in FIG. 11, the passage 180 may include an opening on either end (e.g., so that an object can pass entirely through the passage 180). As described above, one end of the passage 180 may be flush with an end of the body 175 and the other end of the passage 180 may be disposed toward a center of the body 175. However, other orientations of the passage 180 may be used in other examples.

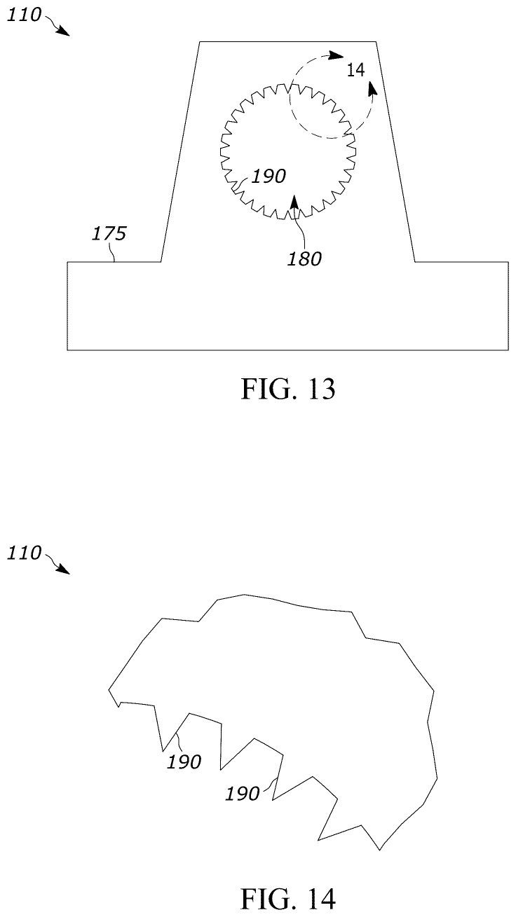

As shown in FIGS. 13 and 14, some forms of the passage 180 may include teeth 190. The teeth 190 of the passage 180 may correspond to the teeth 175 of the extension 140. For example, the teeth 190 may extend entirely around the inner perimeter of the passage 180. Additionally, there may be thirty teeth 190, with each tooth spaced apart from adjacent teeth 190 may about twelve degrees. The teeth 190 may have a complementary shape to the teeth 175. For example, the teeth 190 may be a plurality of angled bodies, with a substantially planar surface forming the space between adjacent teeth 190. However, the teeth 190 may be spaced and/or shaped differently if the teeth 175 of the extension 140 are shaped differently.

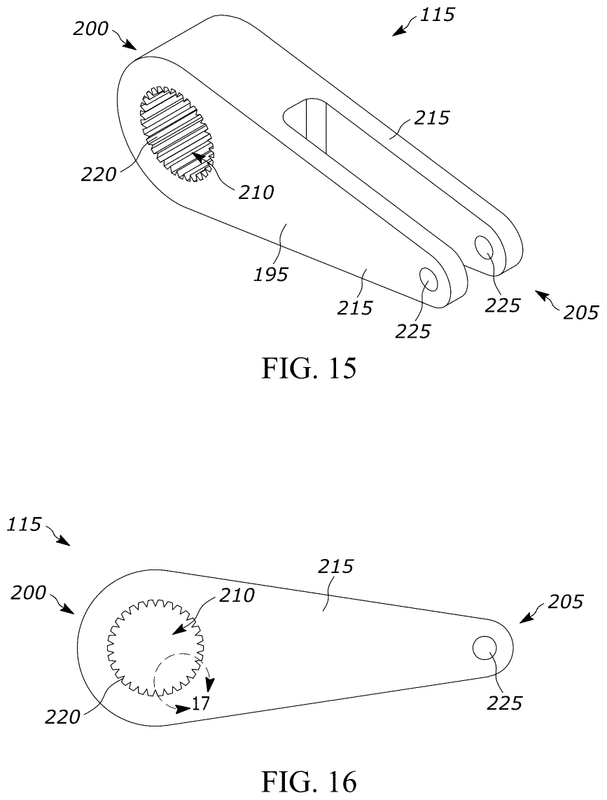

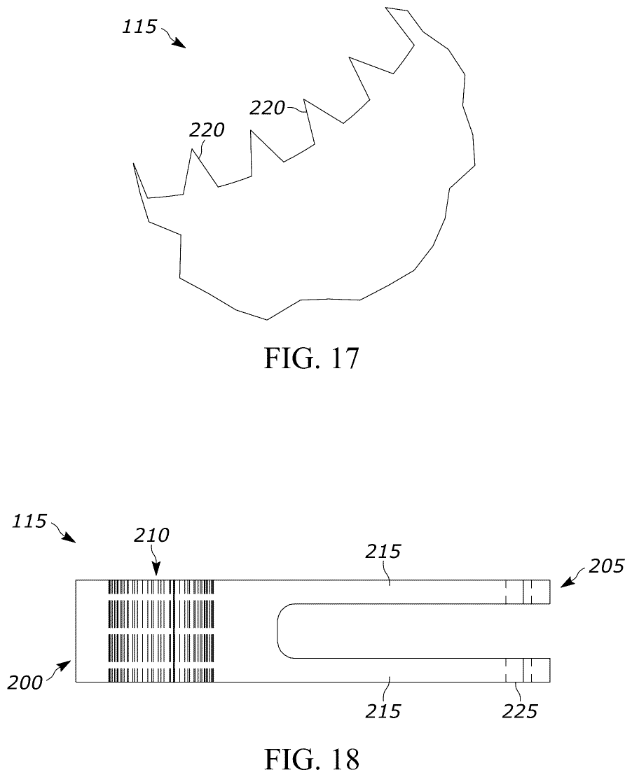

FIGS. 15 to 18 illustrate the return spring bracket 115. The return spring bracket 115 may include a body 195 with a first end 200 and a second end 205. The first end 200 may include a mounting aperture 210. The second end may include a pair of spaced apart prongs 215.

As shown in FIGS. 15 to 17, the mounting aperture 210 may include a plurality of teeth 220. The teeth 220 of the mounting aperture 210 may correspond to the teeth 175 of the extension 140. For example, the teeth 220 may extend entirely around the inner perimeter of the mounting aperture 210. Additionally, there may be thirty teeth 220, with each tooth spaced apart from adjacent teeth 220 may about twelve degrees. The teeth 220 may have a complementary shape to the teeth 175. For example, the teeth 220 may be a plurality of angled bodies, with a substantially planar surface forming the space between adjacent teeth 220. However, the teeth 220 may be spaced and/or shaped differently if the teeth 175 of the extension 140 are shaped differently.

As shown in FIG. 18, the mounting aperture 210 may extend entirely through the body 195 so that an opening to the mounting aperture 210 is accessible on either side. The teeth 220 may also extend entirely along the length of the mounting aperture 210 through the body 195. However, other examples may include a mounting aperture 210 that extends only partially through the body 195.

Returning to FIG. 15, the prongs 215 may be elongated portions that extend away from the mounting aperture 210. Each prong 215 may include an opening 225 that is aligned with the opening 225 on the other prong 215.

Returning to FIGS. 1 and 2, the drive shaft 105, the actuating arm bracket 110, and the return spring bracket 115 may be assembled to form the interrupter device 100. In use, the drive shaft 105 may rotate between the actuating arm bracket 110 and the return spring bracket 115 to limit or prevent arcing.

When assembling the interrupter device 100, an extension 140 may be connected to each end of the drive shaft 105. The extension 140 may serve to interface between the drive shaft 105 and respective the actuating arm bracket 110 and the return spring bracket 115.

To connect an extension 140 to the drive shaft 105, the first end 120 may be disposed proximate to the first portion 145. The first end 120 of the drive shaft 105 may be oriented so that the splined shape (e.g., hexagonal shape) substantially matches the shape of the internal perimeter of the first portion 145. Specifically, the first end 120 and the first portion 145 may be positioned so that the end aperture 135 of the drive shaft 105 is oriented in the same direction as the aperture 160 of the extension 140.

The first end 120 may then be inserted into the first portion 145 of the extension 140. Once inserted, the end aperture 135 and the aperture 160 may be aligned. The splined shape of the first end 120 and the inner surface of the first portion 145 may limit relative rotation between the drive shaft 105 and the extension 140. For example, the angled surfaces may limit or prevent slipping between the drive shaft 105 and the extension 140.

The inner surface of the first portion 145 may be shaped and sized to snuggly receive the first end 120 of the drive shaft 105. For example, upon inserting the first end 120, the first end 120 may be frictionally engaged within the first portion 145. To better secure the extension 140 to the drive shaft 105, a fastener 230 may be inserted through the end aperture 135 and the aperture 160. The fastener 230 may be a pin, although any type of fastener may be used.

Because the end aperture 135 and the aperture 160 are pre-formed before assembly, a technician installing the interrupter device 100 may use the apertures 135, 160 to ensure proper installation of the drive shaft 105. In other words, the first end 120 of the drive shaft 105 may be inserted until the end aperture 135 comes into alignment with the aperture 160. At this point, the drive shaft 105 may be sufficiently inserted into the extension 140 to limit accidental insertion.

Including the pre-formed apertures 135, 160 helps to minimize damage caused by not properly installing the drive shaft 105. For example, if the apertures 135, 160 are not pre-formed, a technician may blindly insert the drive shaft 105 into the first portion 145. Because of the engagement (e.g., frictional, threaded, etc.) between the first end 120 and the first portion 145, it may be difficult to precisely determine whether the drive shaft 105 has been fully inserted. The technician then must drill a hole through the first end 120 and the first portion 145, to create the apertures for the pin, without confirmation that the first end 120 is fully inserted. If the technician selects an incorrect location to drill the hole (e.g., because the first end 120 is not fully inserted) the drive shaft 105 and/or the extension 140 may need to be replaced and a new aperture drilled into the replacement part(s). Pre-forming the apertures 135, 160 during the manufacturing process simplifies the assembly of the interrupter device 100 and reduces wasted materials from improper drilling locations.

A similar process may be performed to connect an additional extension 140 to the second end 125 of the drive shaft 105. For example, the second end 125 may be inserted into the first portion 145 of the respective extension 140 until the end aperture 135 and the aperture 160 are aligned. Then a fastener 230 (e.g., a pin) may be inserted through the aligned apertures 135, 160.

In some examples, the drive shaft 105 and the extensions 140 may be pre-assembled and shipped to a user already connected to one other. In other examples, the drive shaft 105 and extensions 140 may be shipped uncoupled and a technician may assemble the extensions 140 to the drive shaft 140. The assembly process may be simplified because the apertures 135, 160 are pre-formed and do not need to be drilled during the assembly process.

The drive shaft 105, with the connected extension 140, may be connected to the actuating arm bracket 110. Specifically, the second and third portions 150, 155 may be inserted through the passage 180. The diameter of the first portion 145 may be larger than the diameter of the passage 180 and may act as a stop to limit over-insertion of the extension 140 into the passage 180.

The third portion 155 may be oriented so that the teeth 170 mesh with the teeth 190 of the passage 180. The third portion 155 may be approximately the length of the passage 180 so that when fully received, the first and second portions 145, 150 are both outside of the passage 180.

In some forms, the hole 165 of the second portion 150 may be positioned outside of the passage when the third portion 155 is fully inserted into the passage 180. The second portion 150 may be oriented so that the hole 165 is proximate to the passage 180. After the third portion 155 is fully inserted, a fastener 235 (e.g., a similar fastener as inserted through the apertures 135, 160) may be inserted through the hole 165. The fastener 235 may act as a stop in conjunction with the first portion 145. Together, they may limit relative translational movement along the axis of the passage 180. The fastener 235 and the first portion 145 may not limit rotational movement of the drive shaft 105.

A similar process may be performed to connect the additional extension 140 to the return spring bracket 115. For example, the second and third portions 150, 155 may be inserted through the mounting aperture 210. The diameter of the mounting aperture 210 may be substantially the same as the diameter of the passage 180 so the first portion 180 continues to act as a stop. Once the second portion 150 is fully inserted through the mounting aperture 210, a fastener 235 may be inserted through the hole 165 to retain the third portion 155 within the mounting aperture 210.

Once the drive shaft 105 is connected between the actuating arm bracket 110 and the return spring bracket 115, it may be able to rotate to operate as an interrupter device 100. Specifically, the drive shaft 105 may be able to move without loosening from the extensions 140. Additionally, the splined shape of the first and second ends 120, 125 may minimize or prevent slippage within the system because the ends are fit together with a complementary shape on the extension 140. This may also add an additional factor of safety for lateral movements because the drive shaft 105 is pinned in place and the splined shape of the first and second ends 120, 125 remain in contact for a longer duration of time.

If one of the components fails during use, the interrupter device 100 may be at least partially disassembled and the broken component may be replaced with a working one. For example, an extender 140 can be unpinned from the drive shaft 105 and a new extender 140 can be connected. The splined shape and pinned connection may simplify replacing different components as compared to unscrewing the drive shaft 105 and re-drilling apertures.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinarily skilled artisan to modify one or more of the constituent parts for carrying out the various examples of the disclosure. Once armed with the present specification, routine experimentation is all that is needed to determine adjustments and modifications that will carry out the present disclosure.

The above examples are for illustrative purposes and are not intended to limit the scope of the disclosure or the adaptation of the features described herein. Those skilled in the art will also appreciate that various adaptations and modifications of the above-described preferred examples can be configured without departing from the scope and spirit of the disclosure. Therefore, it is to be understood that, within the scope of the appended claims, the disclosure may be practiced other than as specifically described.

What is claimed is:

1. An interrupter device comprising:
a drive shaft configured to be driven to rotate in a first direction and/or in a second direction, the drive shaft including,
a first end having a first splined shape and a first end opening,
a second end having a second splined shape, and
a central portion disposed between the first end and the second end, wherein the central portion has a cylindrical shape;
a first extension removably connected to the first end, the first extension including,
a first portion having,
a cavity with a shape complementary to the first splined shape, and
a first portion opening extending into the cavity, and
a second portion directly coupled to the first portion and including a plurality of teeth; and
a bracket including a bracket opening with a plurality of bracket teeth spaced around an inner surface of the bracket opening;
wherein the first end is configured to be received in the cavity so that the first end opening is aligned with the first portion opening;
wherein the first end opening and the first portion are configured to receive a pin; and
wherein the drive shaft and the first extension are configured to rotate together.

2. The interrupter device of claim 1, wherein the first extension further includes a third portion directly coupled to the second portion, and wherein the third portion is configured to pass entirely though the bracket opening.

3. The interrupter device of claim 2, wherein the third portion includes a third portion opening that is configured to receive a fastener and limit translational movement relative to the bracket.

4. The interrupter device of claim 1, wherein the first extension includes a stepped surface between the first portion and the second portion, and wherein a first portion diameter is greater than a bracket opening diameter.

5. The interrupter device of claim 1, wherein the first splined shape is a hexagon.

6. The interrupter device of claim 1, further comprising a second extension removably connected to the second end, the second extension including,
a fourth portion having,
a cavity with a shape complementary to the second splined shape, and
a fourth portion opening extending into the cavity, and
a fifth portion directly coupled to the fourth portion and including a plurality of teeth.

7. The interrupter device of claim 1, wherein the first splined shape and the second splined shape are identical.

8. A method of assembling an interrupter device, the method comprising,
inserting a first end of a drive shaft into a cavity of an extender, wherein the first end includes a pre-formed first aperture and the extender includes a pre-formed second aperture;
aligning the first aperture with the second aperture; and
inserting a first fastener through the first aperture and the second aperture to secure the drive shaft to the extender;
wherein the first end includes a first splined shape and the cavity includes a second splined shape that is complementary to the first splined shape.

9. The method of claim 8, wherein the first splined shape and the second splined shape are hexagonal.

10. The method of claim 8, further comprising inserting the extender into a bracket, wherein the extender includes a first portion with the cavity and a second portion having extender teeth, and wherein the bracket includes an opening having opening teeth configured to mesh with the extender teeth.

11. The method of claim 10, wherein a width of the first portion is greater than the width of the opening.

12. The method of claim 10, wherein the extender further includes a third portion adjacent to the second portion and having a width smaller than a width of the second portion, and wherein the third portion includes a hole.

13. The method of claim 12, further comprising inserting the third portion entirely through the opening and inserting a second pin through the hole, wherein a length of the pin is greater than a width of the opening, and wherein the pin is configured to limit translational movement between the bracket and the extender.

14. The method of claim 12, further comprising:
inserting a second end of the drive shaft into a second cavity of a second extender, wherein the second end includes a pre-formed third aperture and the extender includes a pre-formed fourth aperture;
aligning the third aperture with the fourth aperture; and
inserting a second fastener through the third aperture and the fourth aperture to secure the drive shaft to the second extender;
wherein the second end includes a third splined shape and the cavity includes a fourth splined shape that is complementary to the third splined shape.

15. The method of claim 14, wherein the first splined shape is the same as the third splined shape.

16. The method of claim 14, wherein the second extender is identical to the first extender.

17. A method of manufacturing an interrupter device, the method comprising,
forming a drive shaft with a cylindrical body and a splined first end, wherein the splined first end is formed with a first aperture;
forming an extender with a splined cavity and a second aperture;
aligning the splined first end with the splined cavity and inserting the first end into the cavity; and
inserting a first fastener through the first aperture and the second aperture to secure the drive shaft to the extender.

18. The method of claim 17, further comprising introducing the drive shaft into the stream of commerce disconnected from the extender.

19. The method of claim 17, further comprising:
forming a second extender with a second splined cavity and a third aperture;
inserting a splined second end of the drive shaft into the second splined cavity, wherein the splined second end is formed with the fourth aperture;
aligning the splined second end with the second splined cavity and inserting the second end into the second splined cavity; and
inserting a second fastener through the third aperture and the fourth aperture to secure the drive shaft to the second extender.

20. The method of claim 17, wherein the first splined end and the splined cavity each have a hexagonal shape.

21.-30. (canceled)
